(19) United States
(12) Patent Application Publication
(10) Pub. No.: US 2024/0002996 A1
(43) Pub. Date: Jan. 4, 2024

(54) An Apparatus For Forming Patterns On A Surface Of A Substate Plate

(71) Applicant: Volframi Oy Ltd, Masku (FI)

(72) Inventor: Jukka Vuoristo, Masku (FI)

(73) Assignee: Volframi Oy Ltd, Masku (FI)

(21) Appl. No.: 18/039,234

(22) PCT Filed: Nov. 23, 2021
(86) PCT No.: PCT/FI2021/000014

§ 371 Date: May 27, 2023

(30) Foreign Application Priority Data
Dec. 2, 2020 (FI) 20207193

(51) Int. Cl. C23C 14/34; C23C 14/04

(52) U.S. Cl. CPC C23C 14/34; C23C 14/042

(57) ABSTRACT

An apparatus for forming patterns on a substrate plate is disclosed. The apparatus includes a first vacuum chamber, a second vacuum chamber, a pump assembly and a valve arrangement. The substrate plate is configured to be situated between the vacuum chambers. The first vacuum chamber includes a mask chamber, a processing chamber, and a process valve between the first vacuum chamber and the second vacuum chamber. The side of the substrate plate on which the patterns are to be formed is placed towards the first vacuum chamber and another side faces the second vacuum chamber. The pump assembly and the valve arrangement are configured in such a way that when the coating process is started, the second vacuum chamber and mask chamber are first depressurised and then the first vacuum chamber and the second vacuum chamber are separated. The process valve is opened, and a deep vacuum is produced in the first vacuum chamber.

### CROSS REFERENCE TO RELATED APPLICATIONS

This application is a national phase of international application PCT/FI2021/000014, filed Nov. 23, 2021, which claims the benefit of priority to Finnish patent application 20207193, filed 2 Dec. 2020, the content of both applications of which are herein incorporated by reference.

### BACKGROUND OF THE INVENTION

### Field of the Invention

The invention relates to an apparatus for forming patterns on a surface of a substrate plate by a process requiring a vacuum or low-pressure conditions, and the apparatus comprises a first vacuum chamber, a second vacuum chamber, valve arrangement, and a pump assembly. The apparatus has a processing area of the apparatus, and the apparatus is configured to receive substrate plates, which substrate plates have a larger surface area than the processing area of the apparatus. The first vacuum chamber and the second vacuum chamber are configured in such way that there is a gap to receive the substrate plate between the vacuum chambers, and the vacuum chambers are on the opposite sides of the substrate plate when the substrate plate is placed in position for the coating process.

Description of Related ArtA vacuum or low-pressure condition are used in many methods where thin layers of coating are applied to the surface of a substrate. These layers serve to protect the substrate from forces that might cause wear or decrease its efficiency or produce patterns on the surface of the substrate. For example, these methods are physical vapor deposition coating (PVD), sputtering coating, cathodic arc deposition, plasma etching, resist stripping process, plasma-enhanced chemical vapor deposition (PECVD), the HDMS process and atomic layer deposition. What is common to all these methods is that they require at least low-pressure conditions and most of them require an electric field to accelerate the coating material particles that are discharged at the substrate to be coated. With these coating processes, patterns can be formed on the surface of a substrate.

A good example of vacuum or low-pressure methods is sputtering, which is a technique used to deposit thin films of a material onto a surface. By first creating a gaseous plasma and then accelerating the ions from this plasma into some source material, the source material is eroded by the arriving ions via energy transfer and it is ejected in the form of neutral particles, either individual atoms, clusters of atoms or molecules. For producing plasma, vacuum or low-pressure conditions are needed. These are achieved with vacuum chambers. As these neutral particles are ejected, they will travel in a straight line unless they come into contact with something, such as other particles or a nearby surface. If a surface such as a Si wafer is placed in the path of these ejected particles, it will be coated by a thin film of the source material. Sputtering is widely used for surface cleaning and etching, thin film deposition, surface layer analysis and as sputter ion sources.

A typical sputtering apparatus comprises a vacuum chamber, a cathode assembly, an anode, which can simply form the inside walls of the chamber, and a target attached to the cathode assembly. In the sputtering process, a substrate to be coated is placed within the chamber, opposite to the target. The chamber is evacuated to a low pressure and a suitable gas is introduced to the chamber. A suitable power supply is then utilized to apply a potential between the cathode and anode, thereby generating ions that accelerate towards the cathode assembly, striking the target with sufficient energy to cause the target to partially vaporize. The vaporized target material diffuses throughout the chamber and leaves a deposit in the form of a thin film on the substrate. The target is the sputtering material source. If there is a mask between the substrate and the target (the sputtering source), patterns can be formed on the substrate.

Touch surfaces are plates or similar structures having some electric control properties, such as on-off switches or slide controllers. These are implemented on walls, windows, panels, or other surfaces by depositing various conductive or resistive patterns on the surface that are affixed to a plate or a similar structure that is joined to said surface. But even though the circuit patterns are simple, they are not easy to produce. Lithographic, etching, dispensing or similar processes are commonly used. However, if the aim is to apply the conductive or resistive pattern directly onto the surface during manufacturing, for example on a window panel, quite a few problems arise because the panels are quite big, and using traditional methods may be impossible, cumbersome or at least excessively time-consuming. Using sputtering or other techniques to apply a protective coating or conductive or resistive patterns is usually out of the question, because sputtering apparatuses must be larger than the surface plate selected for processing, because the plate must fit inside the apparatus in its entirety. This makes the apparatus quite cumbersome and expensive. It must be noted that similar problems are evident for other methods where a vacuum or low-pressure condition are used for coating a surface.

Patent publication U.S. Pat. No. 4,478,701 discloses a sputtering apparatus for depositing thin films on substrates. However, its construction is such that using it for large plates, such as described before, is a practical impossibility.

Patent publication FI20187191 discloses a sputtering apparatus for depositing thin films on a substrate plate. The apparatus is designed in such a way that it is capable handling large plates, i.e. plates larger than the processing area of the apparatus. However, there is a possibility that the substrate plate bends or otherwise spoils during depressurisation. Also, the sputtering source or other coating devices in the vacuum chamber may pollute the surface of the substrate plate in an undesirable manner.

### SUMMARY OF THE INVENTION

An object of the invention is a solution that can significantly reduce the disadvantages and drawbacks of the prior art. In particular, the object of the invention is a solution where an apparatus is provided that allows producing patterns on large substrate plates (the area of the plate is larger than the processing area of the apparatus) in such a way that possible transformation of the substrate plate is minimized.

The objects of the invention are attained with an arrangement that is characterised by what is stated in the independent patent claim. Some advantageous embodiments of the invention are disclosed in the dependent claims.

The invention is an apparatus for forming patterns on a substrate plate comprising a first vacuum chamber, a second vacuum chamber, a pump assembly, and a valve arrangement. A substrate plate is configured to be situated between the vacuum chambers. The first vacuum chamber comprises a mask chamber, a processing chamber, and a process valve between said chambers. The side of the substrate plate on which the patterns are to be formed is placed towards the first vacuum chamber and another side faces the second vacuum chamber. The pump assembly and the valve arrangement are configured in such a way that when the coating process is started the second vacuum chamber and mask chamber are first depressurised and then the first vacuum chamber and the second vacuum chamber are separated. The process valve is opened, and a deep vacuum is produced in the first vacuum chamber.

When reference is made in the text to the upper or the lower parts or respective directions such as down or up, a situation is described in which the apparatus according to the invention is resting on a surface such as a floor. Also, when reference is made to vertical or horizontal directions or surfaces, the apparatus is placed similarly.

It must be noted that the patterns formed by the apparatus can have different electrical properties than other areas on the substrate plate. They can have different visual or haptic properties, i.e. they have different colours, or they feel different when touched. Naturally, the patterns may have all kind of combinations of properties. Also, in addition to the sputtering process, other coating or similar treatments can be used. When there is a reference to a coating process, it may also include a process where a pre-existing coating is removed or otherwise re-treated.

In one embodiment of the invention is an apparatus for forming patterns on a surface of a substrate plate by a process requiring a vacuum or low-pressure conditions, and the apparatus comprises a first vacuum chamber, a second vacuum chamber, a valve arrangement, and a pump assembly, and the apparatus has a processing area of the apparatus. The apparatus is configured to receive substrate plates, which substrate plates have a larger surface area than the processing area of the apparatus. The first vacuum chamber and the second vacuum chamber are configured in such way that there is a gap to receive the substrate plate between the vacuum chambers, and the vacuum chambers are on the opposite sides of the substrate plate when the substrate plate is placed in a position for the pattern forming process. In one advantageous embodiment of the invention, the first vacuum chamber comprises a mask chamber, an arrangement to receive a mask, a process chamber, a process source, and a process valve between the mask chamber and the process chamber. The process source is inside the process chamber and the arrangement to receive the mask is inside the mask chamber. The pump assembly and the valve arrangement are configured to pressurise the second vacuum chamber and the mask chamber to an equal base pressure when a pattern forming process is started, and the valve arrangement is configured to separate the first vacuum chamber from the second vacuum chamber when the base pressure is achieved. When the first vacuum chamber and the second vacuum chamber are separated, the process valve is opened and the pump assembly and the valve arrangement are configured in a such a way that the first vacuum chamber is further depressurised, and when the process valve is open, the process source is exposed to the mask chamber.

In one embodiment of the apparatus, the coating process is a sputtering process, and the process source is a sputtering source.

In a second embodiment of the apparatus, the pump assembly comprises at least a roughing pump system and a deep-vacuum pump, and the roughing pump system is configured to produce the base pressure, and the deep-vacuum pump is configured to depressurise the first vacuum chamber when the first vacuum chamber and the second vacuum chamber are separated.

In a third embodiment of the apparatus, the roughing pump system comprises two roughing pumps: a first roughing pump and a second roughing pump, and the first roughing pump is reserved for the second vacuum chamber and the second roughing pump is reserved for the mask chamber. In a fourth embodiment of the apparatus, the valve arrangement comprises a first valve between the second vacuum chamber and the roughing pump system and a second valve between the mask chamber and the roughing pump system. In a fifth embodiment of the apparatus, the valve arrangement further comprises a third valve between the process chamber and the deep-vacuum pump. In a sixth embodiment of the apparatus, the valve arrangement comprises a fourth valve between the mask chamber and the deep-vacuum pump and the fourth valve is configured to open when the base pressure is achieved.

In a seventh embodiment of the apparatus, the valve arrangement and the pump assembly are configured to further depressurise the second vacuum chamber after the base pressure has been achieved.

In an eighth embodiment of the apparatus, the first vacuum chamber and the second vacuum chamber are movable in relation to each other in order to adjust the width of the gap reserved for the substrate plate.

In a ninth embodiment of the apparatus, the first vacuum chamber comprises a first vacuum ring arrangement and the second vacuum chamber comprises a second vacuum ring arrangement, and the vacuum ring arrangements are configured to seal the substrate plate surfaces between them when the apparatus is in use.

In a tenth embodiment of the apparatus, the first vacuum ring arrangement is configured to encircle the processing area of the apparatus. In an eleventh embodiment of the apparatus, the first vacuum ring arrangement and the second vacuum ring arrangement are configured in such a way that the areas outlined by the vacuum ring arrangements on the both substrate plate surfaces coincide, i.e. they are in same position and have the same size and shape on both substrate plate surfaces.

In a twelfth embodiment of the apparatus, the apparatus comprises a process chamber transfer plate, and the process chamber transfer plate comprises two or more process chambers, and the apparatus further comprises an arrangement for moving the process chamber transfer plate in such a way that the process chamber in the first vacuum chamber is replaceable.

In a thirteenth embodiment of the apparatus, the process chambers on the process chamber transfer plate are configured to be connected to the process valve. In a fourteenth embodiment of the apparatus, the process chambers on the process chamber transfer plate are configured to be connected to the mask chamber. In an embodiment of the apparatus, at least one process chamber on the process chamber transfer plate contains the sputtering source.

In a fourteenth embodiment of the apparatus, the valve arrangement is configured to isolate the first vacuum chamber when the process valve between the mask chamber and the process chamber is opened.

One embodiment of the invention is a method for forming patterns on a surface of a substrate plate with a coating process. In one advantageous embodiment of the invention, the apparatus described previously is used, and the method comprises steps where the substrate plate is placed inside through the gap until the area to be coated is between the vacuum chambers, and the apparatus is positioned in a such way that the substrate plate is between the vacuum chambers and the vacuum chambers are moved towards each other so that the edges of the vacuum chambers are tightly pressed against the surfaces of the substrate plate. The method further comprises steps where air is pumped out of the vacuum chambers and the pressure is kept equal in both vacuum chambers, and when the desired pattern is produced on the substrate plate, ambient pressure is restored to both vacuum chambers and the substrate plate is released and repositioned.

In one embodiment of the method the apparatus comprises a substrate surface heater inside the second vacuum chamber, and the area on the substrate plate where the pattern to be produced is heated from the opposite surface by the substrate surface heater inside the second vacuum chamber during the coating process.

It is an advantage of the invention that it provides an apparatus that makes it possible to sputter patterns on a substrate plate that is larger than the sputtering apparatus. Using the apparatus significantly improves the results of manufacturing touch-sensitive surfaces. Also, the invention decreases the possibility of causing unwanted effects or bending of the substrate plate to be coated. The invention is also suitable for many kinds of coating processes using a vacuum or low-pressure. Some embodiments of the invention make it possible to use a different surface treatment or treatments in addition to vacuum or low-pressure processes with the same apparatus. The invention makes the roughing phase more controlled and safer for the substrate plate.

The invention also protects the coating arrangements in the first vacuum chamber.

One advantage of the invention is that it is fast in use, and the apparatus is small in size. The invention also keeps the opposing surfaces of the substrate plate separate during the coating processes.

It is a further advantage of the invention that it reduces the need to attach separate conductive pattern arrangements, for example a touch-sensitive surface arrangement, to a large plate.

It is a further advantage of the invention that it prevents process gases spreading to the other side of the substrate plate. Also, less process gasses are required.

### BRIEF DESCRIPTION OF THE SEVERAL VIEWS OF THE DRAWINGS

Further advantages, features, and details of the various embodiments of this disclosure will become apparent from the ensuring description of a preferred exemplary embodiment and with the aid of the drawings. The features and combinations of features recited below in the description, as well as the features and feature combination shown after that in the drawing description or in the drawings alone, may be used not only in the particular combination received, but also in other combinations on their own, without departing from the scope of the disclosure.

In the following, the invention is described in detail. The description refers to the accompanying drawings, wherein:

FIG. 1 shows a simplified example of an apparatus in accordance with an embodiment,

FIG. 2 shows a second example of an apparatus in accordance with an embodiment,

FIG. 3 shows a third example of an apparatus in accordance with an embodiment,

FIG. 4 shows a fourth example of an apparatus in accordance with an embodiment,

FIG. 5 shows a fifth example of an apparatus in accordance with an embodiment,

FIG. 6a shows an example of a process chamber transfer plate,

FIG. 6b shows a second example of a process chamber transfer plate, and

FIG. 7 shows a sixth example of an apparatus in accordance with an embodiment.

### DETAILED DESCRIPTON OF THE INVENTION

As used throughout the present disclosure, unless specifically stated otherwise, the term “or” encompasses all possible combinations, except where infeasible. For example, the expression “A or B” shall mean A alone, B alone, or A and B together. If it is stated that a component includes “A, B or C”, then, unless specifically stated otherwise or infeasible, the component may include A, or B, or C, or A and B, or A and C, or B and C, or A and B and C. Expressions such as “at least one of” do not necessarily modify an entirety of the following list and do not necessarily modify each member of the list, such that at least one of “A, B, and C” should not be understood as including only one of A, only one of B, only one of C, or any combination of A, B, and C.

The embodiments in the following description are given as examples only and someone skilled in the art can carry out the basic idea of the invention also in some other way than what is described in the description. Though the description may refer to a certain embodiment or embodiments in several places, this does not mean that the reference would be directed towards only one described embodiment or that the described characteristic would be usable only in one described embodiment. The individual characteristics of two or more embodiments may be combined and new embodiments of the invention may thus be provided.

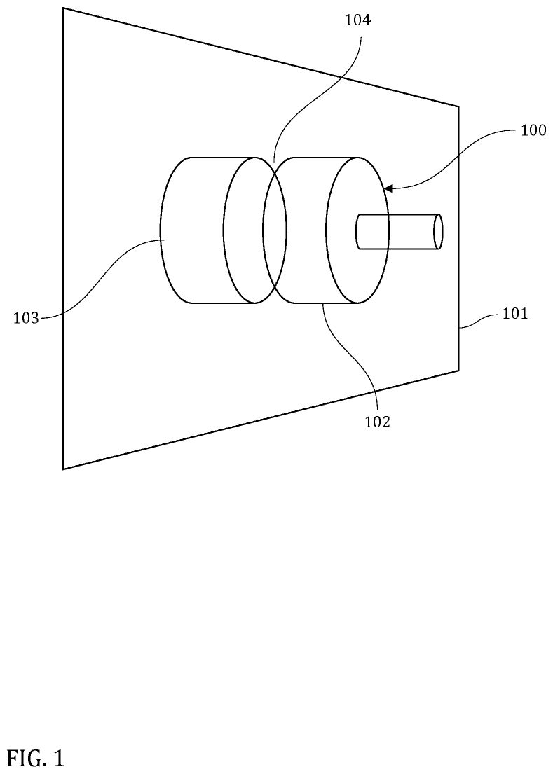

FIG. 1 shows a simplified example of an embodiment of an apparatus 100. The apparatus is for forming patterns on the surface of a substrate plate 101 by a coating or a similar process requiring a vacuum or low-pressure condition. The apparatus comprises a first vacuum chamber 102 and a second vacuum chamber 103. The first vacuum chamber defines a processing area of the apparatus. The processing area is the area on the substrate plate where the apparatus can form patterns. The substrate plates are larger than the processing area. The first vacuum chamber comprises at least partly arrangements that the process requires for forming the patterns on the substrate plate. These arrangements comprise a process source. The patterns have different properties compared to the other areas on the substrate plate. It must be noted that the pattern may cover whole processing area. The properties of the patterns depend on the process and the process materials being used.

In this example the apparatus 100 is configured to receive substrate plates 101 which are in a vertical orientation, i.e. the short sides of a substrate plate point downwards and upwards. The first vacuum chamber and the second vacuum chamber are configured in such a way that between the chamber is a gap 104 in which the substrate plate is to placed. The apparatus is configured in such a way that the width of the gap is adjustable. This is achieved by making both vacuum chambers movable in relation to each other or by making either of the vacuum chambers movable. It must be noted that the apparatus can be in different positions, i.e. the substrate plates can be also in different positions. There are also embodiments where the apparatus is rotatable or it can be in a different position, so it can receive substrate plates that are in different positions as well.

The first vacuum chamber 102 and the second vacuum chamber 103 have openings in the gap 104. The opening in the first vacuum chamber allows forming patterns on the surface of the substrate plate 101 by the coating process. In some processes, there is a mask between the surface of the substrate plate and the process source. The mask is shaped to form the desired patterns. In some embodiments there is an arrangement for replacing the mask with another mask. In some embodiments the second vacuum chamber is for heating the substrate plate with a substrate surface heater. The heated area is on the opposite side of the substrate plate in relation to the area where the patterns are to be formed. The heating serves to dehydrate the substrate plate and to improve adhesion.

When the substrate plate 101 is placed in the apparatus 100, the gap is opened, and the vacuum chambers are moved away from each other. Of course, there are embodiments where the substrate plate is lifted into place. And, of course, the substrate plate may have different positions in addition to the vertical position. In those embodiments, the apparatus is positioned accordingly. The movements of the vacuum chambers in relation to the substrate plate are then similar. When the substrate plate is placed in such a way that the area where the patterns are to be formed is at the opening of the first vacuum chamber 102, the gap is closed. When this is done, the vacuum chambers are tightly pressed against the substrate plate. The substrate plate works as a barrier between the first vacuum chamber and the second vacuum chamber. The vacuum chambers and the substrate plate are positioned in such a way that air can be pumped out of the chambers and a vacuum or a low-pressure environment can be formed in the chambers. In some embodiments there is a sealing arrangement at least on some parts of the edges of the first vacuum chamber or on the second vacuum chamber or on both. The sealing arrangement improves the airtightness of the vacuum chambers. The sealing arrangement is configured to hold the substrate plate during the coating process and to release the substrate plate when the substrate plate is to be repositioned or removed. Also, the sealing arrangement protects vacuum conditions in the chambers by preventing leaks.

In some embodiments, the apparatus 100 or some parts of it are movable along the substrate plate 101, which is kept stationary. Of course, there are embodiments where both the apparatus and the substrate are movable when adjusting the pattern to be formed on the substrate plate.

The first vacuum chamber 102 and the second vacuum chamber 103 are separate during the pattern forming process, i.e. gasses and other process materials inside the first vacuum chamber and the second vacuum chamber do not mix. This allows introducing process gas only to the first vacuum chamber. Also, the surface of the substrate plate that faces the second vacuum chamber remains clean and unblemished by the process material.

The first vacuum chamber comprises two chambers: a mask chamber and a process chamber, and a process valve between said chambers. The opening of the first vacuum chamber is in the mask chamber. Therefore, the mask chamber is pressed against the substrate plate during the coating process. Inside the processing chambers is the process source. The process source provides material or similar prerequisite arrangements for the process. During the pattern forming process, both vacuum chambers are pressurised to an equal degree, which is called the base pressure, and more precisely, the pump assembly and the valve arrangement are configured to pressurise the second vacuum chamber and the mask chamber to the base pressure. The base pressure amounts to a low pressure or a near-vacuum. This prevents the substrate plate 101 from breaking or bending if there is a pressure difference between the first vacuum chamber 102 and the second vacuum chamber 103. To control the pressure in both vacuum chambers, there is a valve system and a pump assembly (not presented in FIG. 1). The valve arrangement is configured to separate the first vacuum chamber from the second vacuum chamber when the base pressure has been achieved. When the first vacuum chamber and the second vacuum chamber are separated, the process valve is opened, and the pump assembly and the valve arrangement are configured in a such a way that the first vacuum chamber is further depressurised. When the process valve is open, the process source is exposed to the mask chamber, and the patterns can be formed on the surface of a substrate plate. The process valve has an aperture. The diameter of the opened aperture depends on the process that the apparatus 100 is used for (i.e. what kind of process source is in the process chamber).

In some embodiments the apparatus 100 and the first vacuum chamber 102 and the second vacuum chamber 103 are configured in such a way that the patterns can be formed on the border areas of the substrate plate 101. In that case the vacuum chambers extend over the edge of the substrate plate. There is a sealing arrangement that maintain a vacuum in both vacuum chambers during the coating process and prevents process gases from spreading from the first vacuum chamber to the second vacuum chamber.

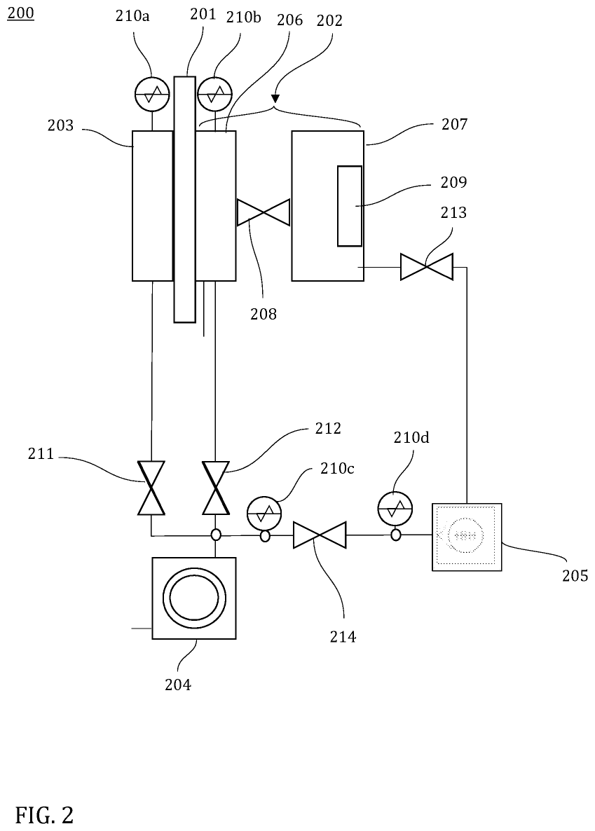

FIG. 2 shows a second example of an apparatus 200 in accordance with an embodiment. The apparatus comprises a first vacuum chamber 202 and a second vacuum chamber 203. Between chambers is a gap in which a substrate plate 201 can be placed for treatment. The apparatus further comprises a valve arrangement and a pump assembly. The valve arrangement comprises a multitude of valves and the pump assembly comprises a roughing pump system 204 and a deep-vacuum pump 205. Also, the apparatus further comprises a sensor arrangement and a pipe arrangement. The sensor arrangement comprises at least a multitude of pressure sensors 210.

The first vacuum chamber 202 and the second vacuum chamber 203 are located directly opposite to each other, with the substrate plate 201 placed between them during the pattern forming process. The diameter and shape of the vacuum chamber are the same, or nearly the same for both chambers. The first vacuum chamber and the second vacuum chamber are movable in relation to each other in order to adjust the width of the gap reserved for the substrate plate. The first vacuum chamber comprises a first vacuum ring arrangement and the second vacuum chamber comprises a second vacuum ring arrangement, and the vacuum ring arrangements are configured to seal the substrate plate surfaces between them when the apparatus is in use. The sealing of the substrate plate between chambers is such that there is no or little leakage when the chambers are in a vacuum or low-pressure conditions. The first vacuum ring arrangement circles the processing area of the apparatus 200. Both vacuum ring arrangements are configured in such a way that the areas outlined by the vacuum ring arrangements on both substrate plate surfaces coincide, i.e. they are in the same position and have the same size and shape on both substrate plate surfaces. The substrate plate is placed between the chambers at least partly. If the substrate plate is partly between the chambers, i.e. the edge of the substrate plate is between the chambers, the apparatus 200 comprises an additional sealing arrangement to seal the openings of the chambers. In some embodiments the vacuum ring arrangements comprise two seal rings, and the area between said rings is emptied to a vacuum. This is useful with some processes requiring particularly pure vacuum conditions, and thus that kind of construction is used in the first vacuum ring arrangement.

The first vacuum chamber 202 comprises two chambers: a mask chamber 206 and a process chamber 207, and a process valve 208 between said chambers. In the process chamber is a process source 209. In this example, the process for forming patterns on the substrate plate is a sputtering process and the process source is a sputtering source. The second vacuum chamber also contains other arrangements for using the sputtering process in the apparatus. In some embodiments, the second chamber 203 comprises a two-part construction similar to that of the first vacuum chamber. This type of second vacuum chamber can be used for independent processes on the other side of the substrate plate 201.

The mask chamber 206 comprises an arrangement to receive a mask between the substrate plate 201 and the process source 209. Masks with partial coating are used, which allows coating to be applied only to exposed areas. The masks are typically plates with cutouts for the desired patterns. It must be noted that not all processes used with the apparatus require a mask in all circumstances.

The process valve 208 is configured to be opened when patterns are to be formed on the surface of the substrate plate 201. To expose the process source 209 to the mask, chamber 206 comprises an aperture. The shape and the size of the aperture depends on the process to be used. When closed, the process valve is configured to separate the mask chamber from the process chamber so that gases between said chambers do not mix and different pressure levels can exists in the chambers, i.e. the closed process valve is air-tight. When the process is started, the process chamber is emptied to a vacuum or a near vacuum. When the process valve is to be opened for pattern forming or for some other process, the first chamber (the process chamber and the mask chamber) is isolated from the rest of the apparatus by closing the valves connecting the first chamber to the pipe arrangement and the pump assembly.

The pipe arrangement serves to connect the pump assembly to the first vacuum chamber 202 and the second vacuum chamber 203. The pressure sensors 210 serve to measure chamber pressure levels. The pressure levels are measured in the chambers or in the pipes of the pipe arrangement. The valve arrangement comprises in this embodiment a first valve 211, a second valve 212, a third valve 213 and a fourth valve 214. The valves stop gas from flowing and maintain pressure differences. They also serve safety purposes and to control the processes of the apparatus. The degree to which the valves are opened is adjustable, i.e. the gas flow is adjustable. It must be noted that different embodiments may comprise valves that are not described here.

The roughing pump system 204 comprises a roughing pump. The roughing pump serves to achieve the base pressure inside the mask chamber 206 and the second chamber 203. Producing the base pressure is called the roughing phase. During the roughing phase, the pressure is decreased from ambient air pressure to the base pressure. Also, during the roughing phase the pressure levels in the mask chamber and the second chamber are kept equal. The deep-vacuum pump 205 serves to achieve vacuum conditions at least in the process chamber 207. The pressure level achieved with the deep-vacuum pump are lower than the pressure levels achieved with the roughing pump.

The first valve 211 is between the roughing pump and the second chamber 203. The second valve 212 is between the roughing pump and the mask chamber 206. The third valve 213 is between the deep-vacuum pump 205 and the process chamber 207. The fourth valve is between the deep-vacuum pump 205 and the first valve and the second valve.

In this embodiment the apparatus comprises a first pressure sensor 210a, a second pressure sensor 210b, a third pressure sensor 210c, and a fourth pressure sensor 210d. The first pressure sensor measures the pressure of the second vacuum chamber 203. The second pressure sensor measures the pressure of the mask chamber 206. The third pressure sensor is placed between the first valve 211 and the fourth valve 214. The fourth valve measures the pressure produced by the deep-vacuum pump 205.

When the roughing phase is started, the first valve 211 and the second valve 212 are opened and the roughing pump decreases the pressure levels of the mask chamber 206 and the second chamber 203. The first pressure sensor and the second pressure sensor monitor the chamber pressure levels, and the first valve and the second valve are used to keep the pressure levels equal. The fourth valve 214 and the process valve 208 are kept closed during the roughing phase. When the base pressure is reached in the mask chamber and the second chamber, the second valve is closed, and thus the first chamber 202 and the second chamber are separated from each other and there is no gas flowing between them. The process chamber has an initial vacuum or a low pressure environment. The process valve 208 is opened to allow gas to flow between the mask chamber and the process chamber. After that, the third valve 213 and the fourth valve 214 are opened. The process chamber is exposed to the mask chamber and to the substrate plate 201. The high vacuum pump 205 depressurises the first vacuum chamber for the process of forming patterns. When the required pressure (or a clean state) for the process is achieved, the process phase (i.e. the pattern-forming) can be started. In this embodiment the first valve is kept open during the process phase in order to maintain similar pressure levels in the first chamber and the second chamber. The third pressure sensor and the fourth pressure sensor control the fourth valve 214. When the process is finished, the process valve can be closed. In some embodiments, where the base pressure and the pressure required by the process in the first chamber are similar (i.e. the pressure difference between chambers is not enough to transform the substrate plate), the deep-vacuum pump may not need to be connected to the second chamber.

The roughing phase, in which the pressure decreases from regular atmosphere pressure to base pressure (near vacuum or low pressure), is preferably done slowly, avoiding sudden pressure changes in order to prevent any deformation to or breakage of the substrate plate 201.

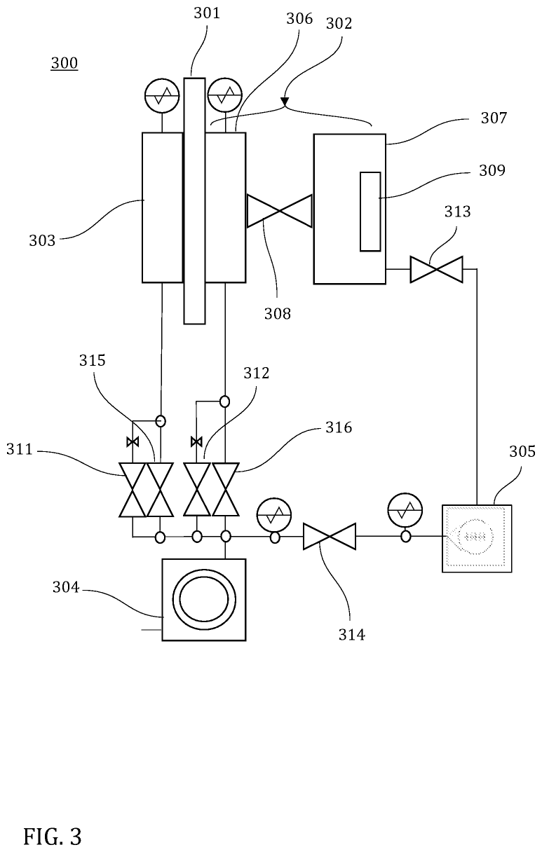

FIG. 3 shows a third example of an apparatus 300 in accordance with an embodiment. The apparatus comprises a first vacuum chamber 302 and a second vacuum chamber 303. Between the chambers is a gap in which a substrate plate 301 can be placed. The apparatus further comprises a valve arrangement and a pump assembly comprising a roughing pump system 304 and a deep-vacuum pump 305. The first vacuum chamber 302 comprises two chambers: a mask chamber 306 and a process chamber 307, and a process valve 308 between said chambers. The valve arrangement comprises a first valve 311, a second valve 312, a third valve 313, a fourth valve 314, a fifth valve 315 and a sixth valve 316. The first, the second, the third and the fourth valves are positioned as presented in the embodiment shown in FIG. 2. The fifth valve is connected in a parallel manner to the first valve and the sixth valve is connected in a parallel manner to the second valve.

When the roughing phase is started, the first valve 311 and the second valve 312 are open and the process valve 308 and the third valve 313 are closed. In the process chamber an initial low pressure (a vacuum or base pressure) exists. Pressure sensors monitor pressure levels in the second vacuum chamber 303 and the mask chamber 306 and said valves are controlled to maintain equal pressure levels in the second vacuum chamber and the mask chamber. When pressure in the second vacuum chamber and the mask chamber is decreased to a sufficiently low level (the exact level depends on the configuration of the chambers and the desired base pressure) the fifth valve 315 and the sixth valve 316 are opened for the final roughing. The first valve and the second valve are closed. When the base pressure is reached, the sixth valve is closed in order to separate the first vacuum chamber 302 from the second vacuum chamber 303. The process valve 308 is opened and then the third valve 313 and the fourth valve 314 are opened and vacuum-pumping is started with the deep-vacuum pump 305. The fifth valve is kept open during the process. The parallel valve construction makes it possible to use different types of valves during different phases of the roughing phase.

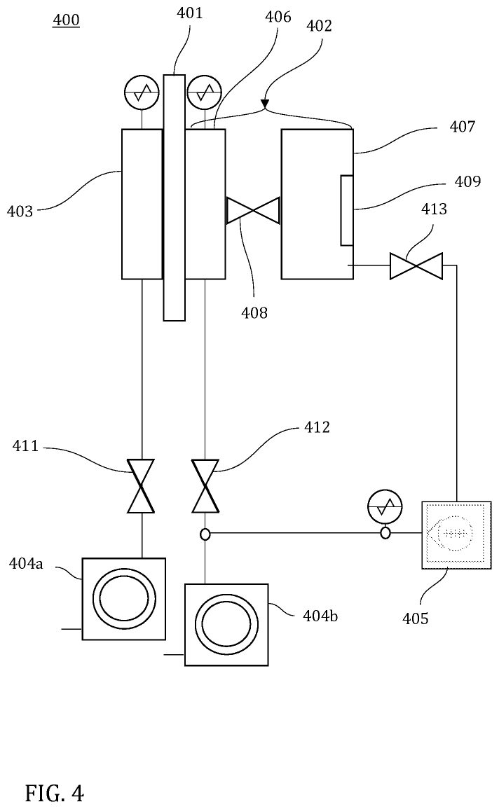

FIG. 4 shows a fourth example of an apparatus 400 in accordance with an embodiment. The apparatus comprises a first vacuum chamber 402 and a second vacuum chamber 403. Between the chambers is a gap in which a substrate plate 401 can be placed. The apparatus further comprises a valve arrangement and a pump assembly comprising the roughing pump system, which comprises a first roughing pump 404a, a second roughing pump 404b and a deep-vacuum pump 405. The first vacuum chamber 402 comprises two chambers: a mask chamber 406 and a process chamber 407, and a process valve 408 between said chambers. The valve arrangement comprises a first valve 411, a second valve 412 and a third valve 413.

The first valve 411 is between the first roughing pump 404a and the second chamber 403. The second valve 412 is between the second roughing pump 404b and the mask chamber 406. The third valve 413 is between the deep-vacuum pump 405 and the process chamber 407.

When the roughing phase is started, the first valve 411 and the second valve 412 are open and the third valve 413 is closed. The first valve connects the first roughing pump 404a to the second vacuum chamber 403 and the second valve connect the second roughing pump 404b to the mask chamber 406. Pressure sensors monitor pressure levels in the second vacuum chamber 403 and the mask chamber 406 and the first valve and the second valve are controlled to maintain equal pressure levels in the second vacuum chamber and the mask chamber. When base pressure is reached by the roughing pumps the second valve closes. Because the second valve and the third valve are closed the first vacuum chamber 402 is isolated from the rest of the apparatus and more specifically from the pipe arrangement. In the process chamber an initial vacuum exists. The process valve 408 is opened to expose the process source to the mask chamber and to balance the pressure levels in the first vacuum chamber. Then the third valve 413 is opened and the deep-vacuum pump 405 starts to depressurise the process chamber 407. When a sufficient vacuum or sufficiently low pressure conditions are reached, the process can be initiated.

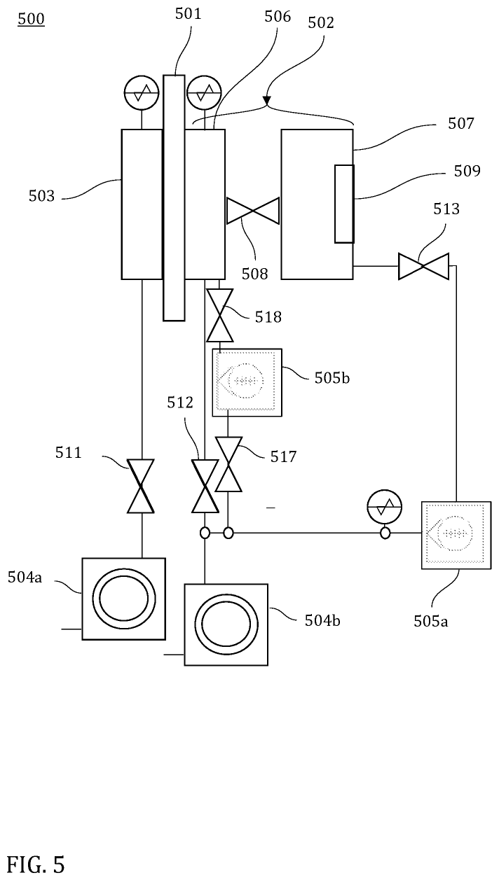

FIG. 5 shows a fourth example of an apparatus 500 in accordance with an embodiment. The apparatus comprises a first vacuum chamber 502 and a second vacuum chamber 503. Between chambers is a gap in which a substrate plate 501 can be placed. The apparatus further comprises a valve arrangement and a pump assembly, which comprises the roughing pump system comprising a first roughing pump 504a, a second roughing pump 504b, a first deep-vacuum pump 505a and a second deep-vacuum pump 505b. The first vacuum chamber 502 comprises two chambers: a mask chamber 506 and a process chamber 507, and a process valve 508 between said chambers. The valve arrangement comprises a first valve 511, a second valve 512, a third valve 513, a seventh valve 517 and an eighth valve 518.

The first valve 511 is between the first roughing pump 504a and the second chamber 503. The second valve 512 is between the second roughing pump 504b and the mask chamber 506. The third valve 513 is between the first deep-vacuum pump 505a and the process chamber 507. The second deep-vacuum pump 505b is positioned between the second roughing pump 504b and the mask chamber 506 in such a way that the seventh valve 517 is between the second roughing pump and the second deep-vacuum pump and the eighth valve is between the mask chamber and the second deep-vacuum pump.

When the roughing phase is started the first valve 511 and the second valve 512 are open. The third valve 513 is open for connecting the process chamber 507 to the deep-vacuum pump and thus providing an initial vacuum in the process chamber. The first valve connects the first roughing pump 504a to the second vacuum chamber 503 and the second valve connect the second roughing pump 504b to the mask chamber 506. Pressure sensors monitor pressure levels in the second vacuum chamber 503 and the mask chamber 506 and the first valve and the second valve are used to maintain equal pressure levels in the second vacuum chamber and the mask chamber. When the base pressure level is achieved with the roughing pumps, the second valve is closed. The seventh valve 517 and the eight valve 518 are opened and the second deep-vacuum pump 505b begins to depressurise the mask chamber 507. When the required vacuum in the mask chamber is reached, the third valve 513 and the eighth valve are closed, and then the process valve 508 is opened. Then the third valve is opened and the process chamber 507 and mask chamber 507 are depressurised by the first deep-vacuum pump 505a. When a sufficient vacuum or sufficiently low pressure conditions are reached, the process can be started.

In some embodiments the apparatus for forming patterns on a surface of a substrate plate comprise an arrangement for changing the process chamber participating in the pattern forming process. Said arrangement comprises a process chamber transfer plate. The process chamber transfer plate comprises two or more process chamber modules. The apparatus further comprises an arrangement for moving the process chamber transfer plate in such a way that the process chamber in the first vacuum chamber is changeable. When moving the process chamber transfer plate, the process chamber module connected to the process valve disconnects and the adjacent process chamber module in the process chamber transfer plate can be connected to the process valve. The apparatus comprises a process chamber module sealing arrangement to produce an impermeable connection between the process chamber module and the process valve. Said sealing arrangement corresponds to the vacuum ring arrangements, which are pressed against the substrate plate. Also, connections to the pipe arrangement are configured connect and disconnect when the process chamber transfer plate is moved. In some embodiments each process chamber module comprises its own process valve and when the process chamber module is changed, the process valve in the process chamber module is connected to the mask chamber.

The process chamber modules on the process chamber transfer plate contain at least some of the required parts (such as pumps, source material, etc.) to run defined processes in the process chamber module. Some common parts may be in the stationary part (i.e. non-movable part) of the first vacuum chamber. The process chamber modules can be used in vacuum processes as well, and in chemical and liquid processes. The process chamber modules can be independently configured (all necessary components are embedded in the module) or they can use a common configuration (such as shared vacuum spaces, etc.). The process chamber transfer plate makes it possible to subject the substrate plate that is positioned and fixed in the apparatus to several different types of treatments. This allows for more speed and accuracy.

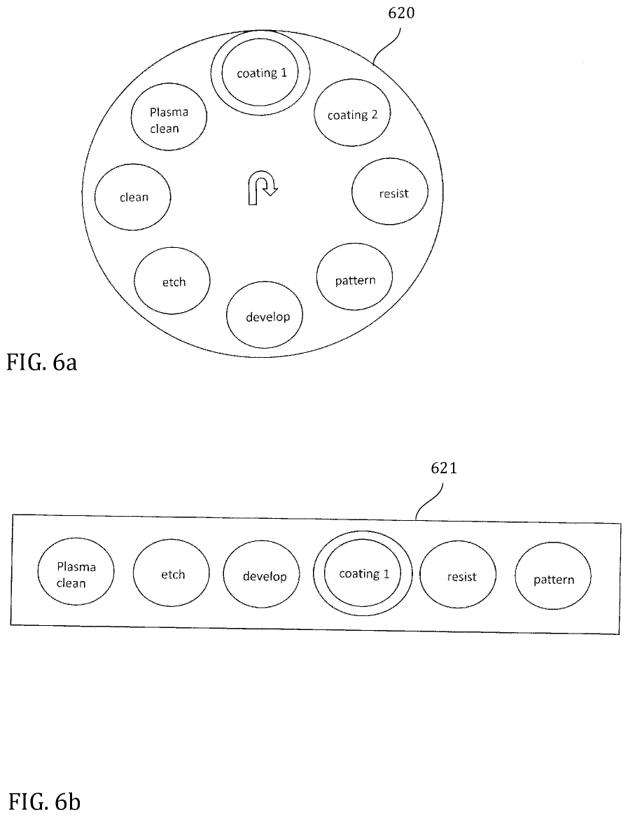

FIG. 6a shows an example of a process chamber transfer plate 620. The process chamber transfer plate is a circular plate comprising eight process chamber modules. Each process chamber module allows for different treatment processes for a substrate plate. Some of the processes require a vacuum and some do not. To select the active process chamber, the circular process chamber transfer plate is rotated until the wanted process chamber module is correctly placed, i.e. the module is positioned in such a way that it can be connected to the process valve or to the mask chamber.

FIG. 6b shows a second example of a process chamber transfer plate 621. The process chamber transfer plate is a long rectangular plate comprising six process chamber modules. To select the active process chamber, the rectangular process chamber transfer plate is moved in a longitudinal direction until the desired process chamber module is correctly placed and can be connected.

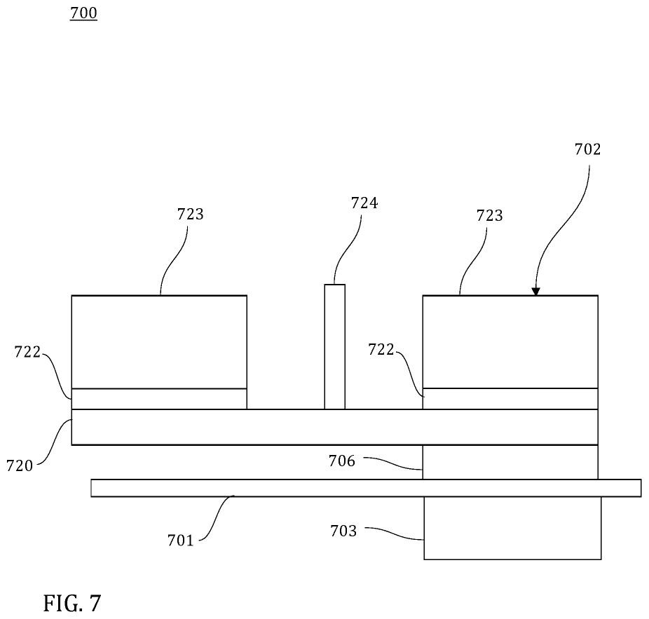

FIG. 7 shows a sixth example of an apparatus 700 in accordance with an embodiment. The figure shows only a part of the apparatus. The apparatus comprises a first vacuum chamber 702 and a second vacuum chamber 703. Between chambers is a gap in which a substrate plate 701 is placed. The apparatus further comprises a valve arrangement, a pump assembly (not presented in the figure) and a process chamber transfer plate 720. The process chamber transfer plate comprises process chamber modules 723 and a rotational axis 724 for rotating the process chamber transfer plate. The process chamber transfer plate comprises a process chamber sealing arrangement 722 for each process chamber module. The first vacuum chamber comprises a process chamber and a mask chamber 706. In this embodiment the first vacuum chamber is formed by rotating the process chamber transfer plate until the desired process chamber module is aligned with the mask chamber and the process chamber sealing arrangement produces a seal between the process chamber module and the mask chamber. Between the process chamber module and the mask chamber is a process valve that is opened when process for the treatment of the substrate plate is to begin.

Some advantageous embodiments of the method and apparatus according to the invention have been described above. The invention is however not limited to the embodiments described above, but the inventive idea can be applied in numerous ways within the scope of the claims.

Since the devices and methods described in detail above are examples of embodiments, they can be modified to a wide extent by the skilled person in the usual manner without departing from the scope of the invention. In particular, the mechanical arrangements and the proportions of the individual elements with respect to each other are merely exemplary. Some preferred embodiments of the apparatus according to the invention have been disclosed above. The invention is not limited to the solutions explained above, but the innovative solutions can be applied in different ways within the limits set out by the claims.

1. An apparatus for forming patterns on a surface of a substrate plate by a process requiring a vacuum or low-pressure conditions, the apparatus comprising:
a first vacuum chamber;
a second vacuum chamber;
valve arrangement;
a pump assembly; and
a processing area of the apparatus; and
wherein:
the apparatus is configured to receive substrate comprising a larger surface area than the processing area;
the first vacuum chamber and the second vacuum chamber are configured and arranged to form a gap to receive the substrate plate between the first vacuum chambers and the second vacuum chamber;
the first vacuum chamber and second chambers are further arranged on opposite sides of the substrate plate when the substrate plate is placed in a position for the process, and there is a process source inside the first vacuum chamber;
the first vacuum chamber comprises a mask chamber, an arrangement to receive a mask, a process chamber, and a process valve arranged between the mask chamber and the process chamber;
the process source is arranged inside the process chamber and the arrangement to receive the mask is arranged inside the mask chamber,
the pump assembly and the valve arrangement are configured and arranged to pressurise the second vacuum chamber and the mask chamber to an equal base pressure when a pattern-forming process is started,
the valve arrangement is configured to separate the first vacuum chamber from the second vacuum chamber when the base pressure is achieved,
when the first vacuum chamber and the second vacuum chamber are separated, the process valve is arranged and configured to be opened and the pump assembly and the valve arrangement are configured such that the first vacuum chamber is further depressurised,
when the process valve is open, the process source becomes exposed to the mask chamber,
the pump assembly comprises a roughing pump system and a deep-vacuum pump, the roughing pump system configured to produce the base pressure, and
the high vacuum pump is configured to depressurise the first vacuum chamber when the first vacuum chamber and the second vacuum chamber are separated.

2. The apparatus according to claim 1, wherein the coating process is a sputtering process and the process source is a sputtering source.

3. The apparatus according to claim 1, wherein the roughing pump system comprises a first roughing pump and a second roughing pump, the first roughing pump configured for the second vacuum chamber and the second roughing pump configured for the mask chamber.

4. The apparatus according to claim 1, wherein the valve arrangement further comprises a first valve arranged between the second vacuum chamber and the roughing pump system, and a second valve arranged between the mask chamber and the roughing pump system.

5. The apparatus according claim 4, wherein the valve arrangement further comprises a third valve arranged between the process chamber and the deep-vacuum pump

6. The apparatus according to claim 4, wherein the valve arrangement further comprises a fourth valve arranged between the mask chamber and the deep-vacuum pump, the fourth valve configured to open when the base pressure is achieved.

7. The apparatus according to claim 1, wherein the valve arrangement and the pump assembly are configured to depressurise the second vacuum chamber after the base pressure has been achieved.

8. The apparatus according to claim 1, wherein the first vacuum chamber and the second vacuum chamber are configured to move in relation to one another so as to adjust width of the gap reserved for the substrate plate.

9. The apparatus according to claim 1, wherein:
the first vacuum chamber comprises a first vacuum ring arrangement;
the second vacuum chamber comprises a second vacuum ring arrangement, and
the first vacuum ring arrangement and the second vacuum ring arrangement are arranged and configured to seal the substrate plate surfaces between them when the apparatus is in use.

10. The apparatus according to claim 9, wherein the first vacuum ring arrangement is configured to encircle the processing area of the apparatus.

11. The apparatus according to claim 9, wherein the first vacuum ring arrangement and the second vacuum ring arrangement are configured such that areas outlined by the first vacuum ring on both substrate plate surfaces coincide or, are in a same position and have a same size and shape on both substrate plate surfaces.

12. The apparatus according to claim 1, further comprising:
a process chamber transfer plate comprising two or more process chambers, and
an arrangement for moving the process chamber transfer plate such that the process chamber in the first vacuum chamber is changeable.

13. The apparatus according claim 12, wherein the two or more process chambers on the process chamber transfer plate are configured to be connected to the process valve.

14. The apparatus according to claim 13, wherein the two or more process chambers on the process chamber transfer 206; 306; 406; 506; 706).

15. The apparatus according to claim 1, wherein the valve arrangement is configured to isolate the first vacuum chamber when the process valve between the mask chamber and the process chamber is opened.
